(19) United States
(12) Patent Application Publication
(10) Pub. No.: US 2019/0228963 A1
(43) Pub. Date: Jul. 25, 2019

(54) SUBSTRATE PROCESSING METHOD AND SUBSTRATE PROCESSING APPARATUS

(71) Applicant: Tokyo Electron Limited, Tokyo (JP)

(72) Inventor: Mitsunori Nakamori, Koshi-shi, Kumamoto (JP)

(21) Appl. No.: 16/337,466

(22) PCT Filed: Sep. 7, 2017
(86) PCT No.: PCT/JP2017/032278

§ 371 Date: Mar. 28, 2019

(30) Foreign Application Priority Data
Sep. 30, 2016 (JP) 2016-194067

(51) Int. Cl. H01L 21/02; H01L 21/67; B08B 3/08

(52) U.S. Cl. CPC H01L 21/02057; H01L 21/67173; B08B 3/08; H01L 21/67051

(57) ABSTRACT

A substrate processing method includes a liquid processing process, a first replacement process, a water-repellent process, a second replacement process and a drying process. In the liquid processing process, a processing liquid containing water is supplied to a substrate. In the first replacement process, the processing liquid is replaced by supplying an organic solvent having a first temperature to the substrate after being subjected to the liquid processing process. In the water-repellent process, the substrate is allowed to be water-repellent by supplying a water-repellent solution to the substrate after being subjected to the first replacement process. In the second replacement process, the water-repellent solution is replaced by supplying the organic solvent having a second temperature higher than the first temperature to the substrate after being subjected to the water-repellent process. In the drying process, the organic solvent is removed from the substrate after being subjected to the second replacement process.

### TECHNICAL FIELD

The embodiments described herein pertain generally to a substrate processing method and a substrate processing apparatus.

### BACKGROUND

Conventionally, in a semiconductor manufacturing process, a drying processing is performed to dry a substrate by removing a processing liquid supplied on the substrate. In this drying processing, however, a pattern formed on the substrate may be collapsed due to a surface tension of the processing liquid.

In this regard, there is known a method of supplying a water-repellent solution to the substrate to allow a surface of the substrate to be water-repellent (see, for example, Patent Document 1). By supplying a solvent having a surface tension smaller than a surface tension of pure water to the substrate allowed to be water-repellent, the pattern collapse can be suppressed.

### PRIOR ART DOCUMENT

Patent Document 1: Japanese Patent Laid-open Publication No. 2012-044065

### DISCLOSURE OF THE INVENTION

### Problems to be Solved by the Invention

Recently, however, the pattern formed on the substrate is getting finer. With such miniaturization of the pattern, the pattern collapse due to the surface tension may take place more easily. Therefore, in the prior art, there is still a room for improvement in suppressing the pattern collapse.

In view of the foregoing, exemplary embodiments provide a substrate processing method and a substrate processing apparatus capable of drying a substrate while suppressing a pattern collapse.

### Means for Solving the Problems

In one exemplary embodiment, a substrate processing method includes a liquid processing process, a first replacement process, a water-repellent process, a second replacement process and a drying process. In the liquid processing process, a processing liquid containing water is supplied to the substrate. In the first replacement process, the processing liquid is replaced by supplying an organic solvent having a first temperature to the substrate after being subjected to the liquid processing process. In the water-repellent process, the substrate is allowed to be water-repellent by supplying a water-repellent solution to the substrate after being subjected to the first replacement process. In the second replacement process, the water-repellent solution is replaced by supplying the organic solvent having a second temperature higher than the first temperature to the substrate after being subjected to the water-repellent process. In the drying process, the organic solvent is removed from the substrate after being subjected to the second replacement process.

### Effect of the Invention

According to the exemplary embodiment, it is possible to dry the substrate while suppressing the pattern collapse.

### BRIEF DESCRIPTION OF THE DRAWINGS

FIG. 1 is a plan view illustrating an outline of a substrate processing system according to an exemplary embodiment.

FIG. 2 is a schematic diagram illustrating a schematic configuration of a processing unit.

FIG. 3 is a schematic diagram illustrating an example configuration of the processing unit.

FIG. 4A is a diagram illustrating example configurations of a first IPA supply source and a second IPA supply source.

FIG. 4B is a diagram illustrating an example configuration of an IPA supply source according to a modification example.

FIG. 5 is a flowchart illustrating a sequence of processings performed by the processing unit.

FIG. 6A is an explanatory diagram for describing a first replacement processing.

FIG. 6B is an explanatory diagram for describing a water-repellent processing.

FIG. 6C is an explanatory diagram for describing a second replacement processing.

FIG. 7 is an explanatory diagram for describing a water-repellent processing according to a modification example.

### DETAILED DESCRIPTION

Hereinafter, exemplary embodiments of a substrate processing method and a substrate processing apparatus will be explained in detail with reference to the accompanying drawings. Here, however, it should be noted that the exemplary embodiments are not limiting.

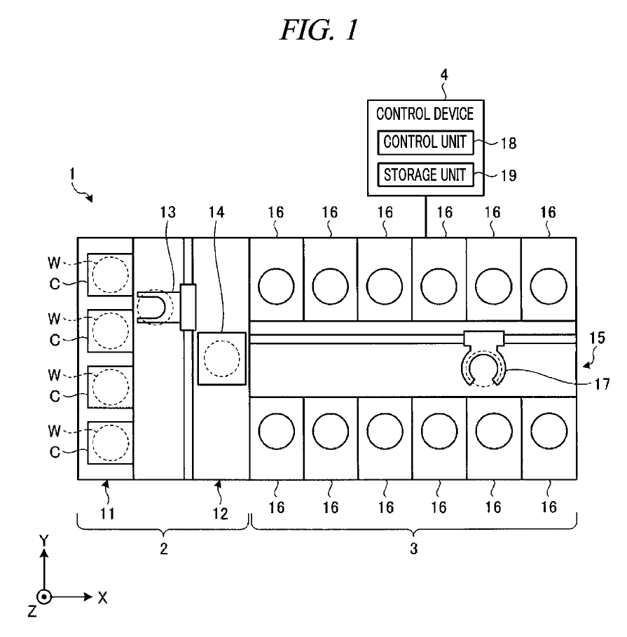

FIG. 1 is a plan view illustrating an outline of a substrate processing system provided with a processing unit according to an exemplary embodiment. In the following, in order to clarify positional relationships, the X-axis, Y-axis and Z-axis which are orthogonal to each other will be defined. The positive Z-axis direction will be regarded as a vertically upward direction.

As illustrated in FIG. 1, a substrate processing system 1 includes a carry-in/out station 2 and a processing station 3. The carry-in/out station 2 and the processing station 3 are provided adjacent to each other.

The carry-in/out station 2 is provided with a carrier placing section 11 and a transfer section 12. In the carrier placing section 11, a plurality of carriers C is placed to accommodate a plurality of substrates (semiconductor wafers in the present exemplary embodiment) (hereinafter, referred to as “wafers W”) horizontally.

The transfer section 12 is provided adjacent to the carrier placing section 11, and provided with a substrate transfer device 13 and a delivery unit 14. The substrate transfer device 13 is provided with a wafer holding mechanism configured to hold the wafer W. Further, the substrate transfer device 13 is movable horizontally and vertically and pivotable around a vertical axis, and transfers the wafers W between the carriers C and the delivery unit 14 by using the wafer holding mechanism.

The processing station 3 is provided adjacent to the transfer section 12. The processing station 3 is provided with a transfer section 15 and a plurality of processing units 16. The plurality of processing units 16 is arranged at both sides of the transfer section 15.

The transfer section 15 is provided with a substrate transfer device 17 therein. The substrate transfer device 17 is provided with a wafer holding mechanism configured to hold the wafer W. Further, the substrate transfer device 17 is movable horizontally and vertically and pivotable around a vertical axis. The substrate transfer device 17 transfers the wafers W between the delivery unit 14 and the processing units 16 by using the wafer holding mechanism.

The processing units 16 perform a predetermined substrate processing on the wafers W transferred by the substrate transfer device 17.

Further, the substrate processing system 1 is provided with a control device 4. The control device 4 is, for example, a computer, and includes a control unit 18 and a storage unit 19. The storage unit 19 stores a program that controls various processings performed in the substrate processing system 1. The control unit 18 controls the operations of the substrate processing system 1 by reading and executing the program stored in the storage unit 19.

Further, the program may be recorded in a computer-readable recording medium, and installed from the recording medium to the storage unit 19 of the control device 4. The computer-readable recording medium may be, for example, a hard disc (HD), a flexible disc (FD), a compact disc (CD), a magnet optical disc (MO), or a memory card.

In the substrate processing system 1 configured as described above, the substrate transfer device 13 of the carry-in/out station 2 first takes out a wafer W from a carrier C placed in the carrier placing section 11, and then places the taken wafer W on the delivery unit 14. The wafer W placed on the delivery unit 14 is taken out from the delivery unit 14 by the substrate transfer device 17 of the processing station 3 and carried into a processing unit 16.

The wafer W carried into the processing unit 16 is processed by the processing unit 16, and then, carried out from the processing unit 16 and placed on the delivery unit 14 by the substrate transfer device 17. After the processing of placing the wafer W on the delivery unit 14, the wafer W returns to the carrier C of the carrier placing section 11 by the substrate transfer device 13.

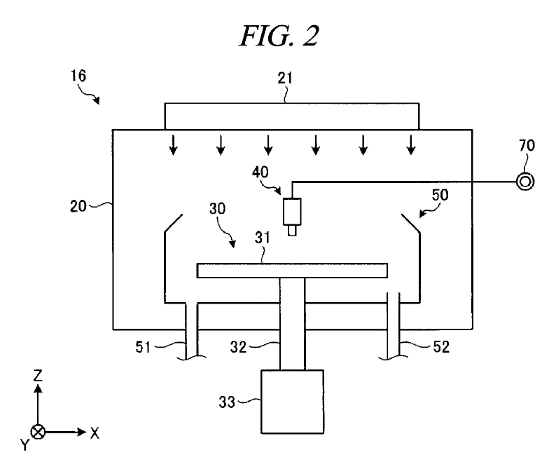

Now, a schematic configuration of the processing unit 16 will be explained with reference to FIG. 2. FIG. 2 is a diagram illustrating a schematic configuration of the processing unit 16.

As illustrated in FIG. 2, the processing unit 16 is provided with a chamber 20, a substrate holding mechanism 30, a processing fluid supply unit 40, and a recovery cup 50.

The chamber 20 accommodates the substrate holding mechanism 30, the processing fluid supply unit 40, and the recovery cup 50. A fan filter unit (FFU) 21 is provided on the ceiling of the chamber 20. The FFU 21 forms a downflow in the chamber 20.

The substrate holding mechanism 30 is provided with a holding unit 31, a support unit 32, and a driving unit 33. The holding unit 31 holds the wafer W horizontally. The support unit 32 is a vertically extending member, and has a base end portion supported rotatably by the driving unit 33 and a tip end portion supporting the holding unit 31 horizontally. The driving unit 33 rotates the support unit 32 around the vertical axis. The substrate holding mechanism 30 rotates the support unit 32 by using the driving unit 33, so that the holding unit 31 supported by the support unit 32 is rotated, and hence, the wafer W held in the holding unit 31 is rotated.

The processing fluid supply unit 40 supplies a processing fluid onto the wafer W. The processing fluid supply unit 40 is connected to a processing fluid source 70.

The recovery cup 50 is disposed to surround the holding unit 31, and collects the processing liquid scattered from the wafer W by the rotation of the holding unit 31. A drain port 51 is formed on the bottom of the recovery cup 50, and the processing liquid collected by the recovery cup 50 is discharged from the drain port 51 to the outside of the processing unit 16. Further, an exhaust port 52 is formed on the bottom of the recovery cup 50 to discharge a gas supplied from the FFU 21 to the outside.

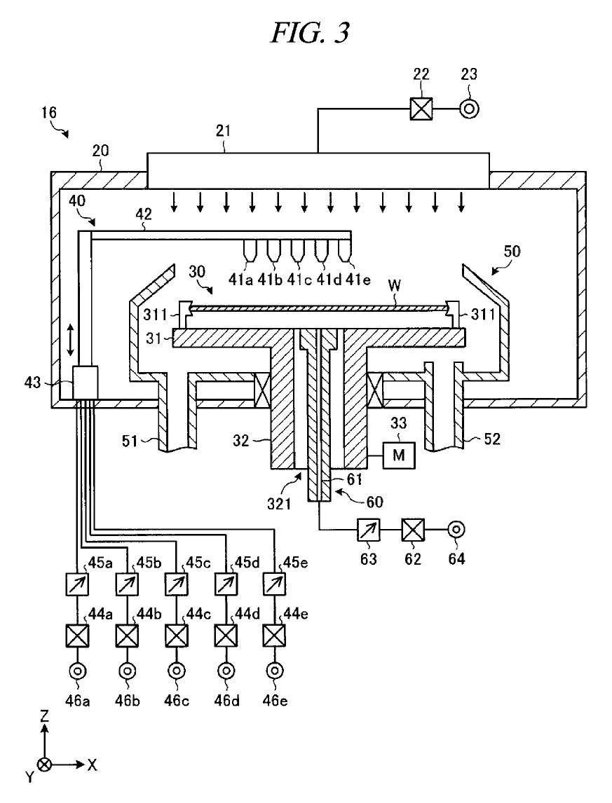

Now, a specific configuration example of the processing unit 16 will be described with reference to FIG. 3. FIG. 3 is a schematic diagram illustrating an example configuration of the processing unit 16.

As depicted in FIG. 3, the FFU 21 is connected to a downflow gas supply source 23 via a valve 22. The FFU 21 discharges a downflow gas (e.g., dry air) supplied from the downflow gas supply source 23 into the chamber 20.

A holding member 311 configured to hold the wafer W from the side thereof is provided at a top surface of the holding unit 31 provided in the substrate holding mechanism 30. The wafer W is horizontally held by this holding member 311 while being slightly spaced apart from the top surface of the holding unit 31. Further, the wafer W is held by the holding unit 31 with a pattern formation surface thereof facing upwards.

The processing fluid supply unit 40 is equipped with a plurality of (here, five) nozzles 41a to 41e, an arm 42 configured to support the nozzles 41a to 41e horizontally and a rotating/elevating mechanism 43 configured to rotate and elevate the arm 42.

The nozzle 41a is connected to a chemical liquid supply source 46a via a valve 44a and a flow rate controller 45a. The nozzle 41b is connected to a CDIW supply source 46b via a valve 44b and a flow rate controller 45b. The nozzle 41c is connected to a first IPA supply source 46c via a valve 44c and a flow rate controller 45c. The nozzle 41d is connected to a water-repellent solution supply source 46d via a valve 44d and a flow rate controller 45d. The nozzle 41e is connected to a second IPA supply source 46e via a valve 44e and a flow rate controller 45e.

A chemical liquid supplied from the chemical liquid supply source 46a is discharged from the nozzle 41a. By way of non-limiting example, DHF (Dilute Hydrofluoric Acid), SC1 (a mixed solution of ammonia, hydrogen peroxide and water), or the like may be used as the chemical liquid. CDIW (pure water of a room temperature) supplied from the CDIW supply source 46b is discharged from the nozzle 41b.

IPA (isopropyl alcohol) having a first temperature supplied from the first IPA supply source 46c is discharged from the nozzle 41c. To elaborate, the nozzle 41c discharges the IPA of a room temperature (e.g., ranging from about 20° C. to about 25° C.). In the following, the IPA of the first temperature may sometimes be referred to as “IPA(RT)”.

The water-repellent solution supplied from the water-repellent solution supply source 46d is discharged from the nozzle 41d. The water-repellent solution is prepared by diluting a water-repellent liquid for allowing the surface of the wafer W to be water-repellent with a thinner at a preset concentration. A silylating agent (or a silane coupling agent) may be used as the water-repellent liquid. Further, an ether solvent or an organic solvent belonging to ketone may be used as the thinner. In the exemplary embodiment, the water-repellent solution having a room temperature is discharged from the nozzle 41d.

IPA having a second temperature supplied from the second IPA supply source 46e is discharged from the nozzle 41e. The second temperature is higher than the first temperature which is the temperature of the IPA. To elaborate, the nozzle 41e discharges the IPA heated to 70° C. In the following, the IPA having the second temperature may sometimes be referred to as “IPA(HOT)”.

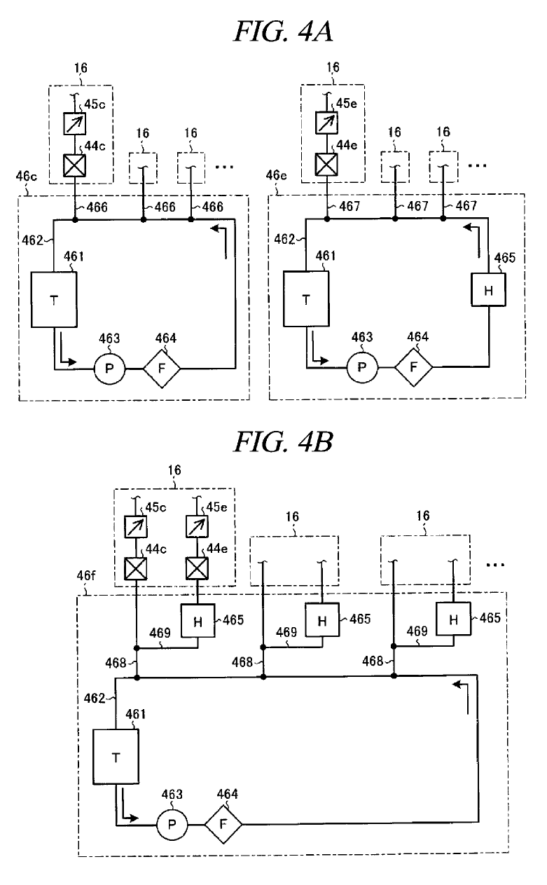

Here, example configurations of the first IPA supply source 46c and the second IPA supply source 46e will be explained with reference to FIG. 4A. FIG. 4A is a diagram illustrating the example configurations of the first IPA supply source 46c and the second IPA supply source 46e.

As depicted in FIG. 4A, each of the first IPA supply source 46c and the second IPA supply source 46e is equipped with: a tank 461 configured to store therein the IPA; and a circulation line 462 coming out from the tank 461 and returning back to the tank 461. The circulation line 462 is provided with a pump 463 and a filter 464. The pump 463 is configured to create a circulation flow coming out from the tank 461 and returning back into the tank 461 through the circulation line 462. The filter 464 is provided downstream of the pump 463 and configured to remove a foreign substance such as a particle included in the IPA.

The second IPA supply source 46e is further equipped with a heating unit 465 in addition to the aforementioned components. The heating unit 465 may be a heater such as, but not limited to, an inline heater and is provided downstream of the filter 464 of the circulation line 462. This heating unit 465 is configured to heat the IPA circulated in the circulation line 462 to the second temperature (70° C.).

A plurality of branch lines 466 is connected to the circulation line 462 of the first IPA supply source 46c. Each branch line 466 is configured to supply the IPA(RT) flowing in the circulation line 462 to a corresponding processing unit 16. Likewise, a plurality of branch lines 467 is connected to the circulation line 462 of the second IPA supply source 46e. Each branch line 467 is configured to supply the IPA(HOT) flowing in the circulation line 462 to a corresponding processing unit 16.

Here, though each processing unit 16 is connected to both the first IPA supply source 46c configured to supply the IPA(RT) and the second IPA supply source 46e configured to supply the IPA(HOT), the processing unit 16 may be connected to a single IPA supply source. Such a configuration will be explained with reference to FIG. 4B. FIG. 4B is a diagram illustrating an example configuration of an IPA supply source according to a modification example.

As shown in FIG. 4B, the processing unit 16 includes an IPA supply source 46f instead of the first IPA supply source 46c and the second IPA supply source 46e.

The IPA supply source 46f is equipped with the tank 461 storing the IPA therein and the circulation line 462 coming out form the tank 461 and returning back to the tank 461. The circulation line 462 is provided with the pump 463 and the filter 464. The pump 463 is configured to create the circulation flow coming out from the tank 461 and returning back into the tank 461 through the circulation line 462. The filter 464 is provided downstream of the pump 463 and configured to remove a contaminant such as a particle included in the IPA.

A plurality of first branch lines 468 is connected to the circulation line 462 of the IPA supply source 46f. Each first branch line 468 is configured to supply the IPA(RT) flowing in the circulation line 462 to a corresponding processing unit 16. Further, each first branch line 468 is connected with a corresponding second branch line 469, and each second branch line 469 is provided with the heating unit 465. Each second branch line 469 is configured to supply the IPA(HOT) heated to the second temperature by the heating unit 465 to a corresponding processing unit 16.

As stated above, the IPA supply source 46f may have the configuration including: the single circulation line 462 through which the IPA(RT) is circulated; the first branch lines 468 through which the IPA(RT) is supplied to the processing units 16; and the second branch lines 469 through which the IPA(HOT) is supplied to the processing units 16. By adopting this configuration, the apparatus configuration can be simplified as compared to the one shown in FIG. 4A.

Further, if the liquid flowing in the circulation line 462 is of a high temperature, foreign substances in the liquid may be agglomerated, or the foreign substances in the liquid are allowed to easily pass through the filter 464 provided at the circulation line 462 as the filter 464 is thermally expanded. That is, a removal efficiency for the foreign substances is deteriorated. On the contrary, by providing the heating unit 465 at the second branch line 469, not at the filter 464, as shown in FIG. 4B, the deterioration of the removal efficiency for the foreign substances can be suppressed.

Furthermore, the second branch lines 469 may be connected to the circulation line 462, not to the first branch lines 468.

As illustrated in FIG. 3, the processing unit 16 is further equipped with a rear surface supply unit 60. The rear surface supply unit 60 is inserted through a hollow portion 321 of the support unit 32 and the holding unit 31. A vertically extended path 61 is formed within the rear surface supply unit 60, and a HDIW supply source 64 is connected to the path 61 via a valve 62 and a flow rate controller 63. HDIW supplied from the HDIW supply source 64 is discharged from the rear surface supply unit 60. The HDIW is, for example, pure water heated to a second temperature.

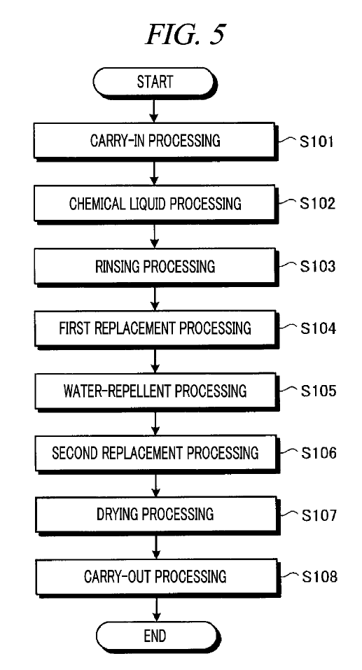

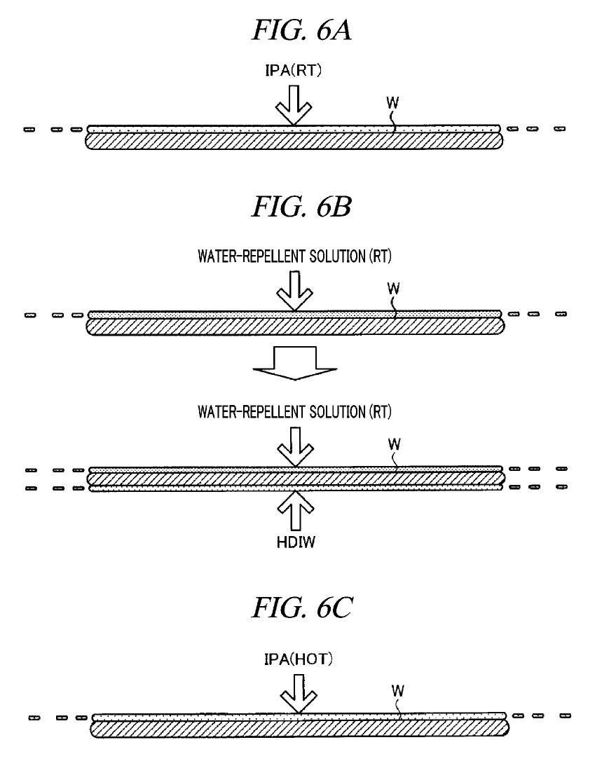

Now, the contents of processings performed by the processing unit 16 will be discussed with reference to FIG. 5 and FIG. 6A to FIG. 6C. FIG. 5 is a flowchart illustrating a sequence of the processings performed by the processing unit 16. FIG. 6A is an explanatory diagram for describing a first replacement processing; FIG. 6B, an explanatory diagram for describing a water-repellent processing; and FIG. 6C, an explanatory diagram for describing a second replacement processing.

Further, a substrate cleaning processing shown in FIG. 5 is carried out as the control unit 18 reads out a program stored in the storage unit 19 of the control device 4 and controls the processing unit 16 and so forth based on the read-out command. The control unit 18 includes a microcomputer having a CPU (Central Processing Unit), a ROM (Read Only Memory), a RAM (Random Access Memory), an input/output port, and so forth, and various kinds of circuits. Further, the storage unit 19 is implemented by a semiconductor memory device such as a RAM or a flash memory or a storage device such as a hard disk or an optical disk.

As shown in FIG. 5, the substrate transfer device 17 (see FIG. 1) carries a wafer W into the chamber 20 of the processing unit 16 (process S101). The wafer W is held by the holding member 311 (see FIG. 3) with the pattern formation surface thereof facing upwards. Then, the control unit 18 rotates the substrate holding mechanism 30 at a preset rotation speed by controlling the driving unit 33.

Subsequently, in the processing unit 16, a chemical liquid processing is performed (process S102). In the chemical liquid processing, the nozzle 41a of the processing fluid supply unit 40 is placed above a central portion of the wafer W. Then, as the valve 44a is opened for a predetermined time period, the chemical liquid such as DHF is supplied onto the surface of the wafer W. The chemical liquid (for example, DHF) supplied on the surface of the wafer W is diffused onto the entire surface of the wafer W by a centrifugal force which is generated when the wafer W is rotated. Accordingly, the surface of the wafer W is processed (for example, cleaned). Thereafter, in the processing unit 16, a rinsing processing is performed (process S103). In the rinsing processing, the nozzle 41b of the processing fluid supply unit 40 is placed above the central portion of the wafer W. Then, as the valve 44b is opened for a preset time period, the CDIW is supplied onto the surface of the wafer W. The CDIW supplied on the surface of the wafer W is diffused onto the entire surface of the wafer W by the centrifugal force which is generated by the rotation of the wafer W. As a result, the chemical liquid remaining on the surface of the wafer W is washed away by the CDIW.

Next, in the processing unit 16, the first replacement processing is performed (process S104). In the first replacement processing, the nozzle 41c of the processing fluid supply unit 40 is placed above the central portion of the wafer W. Then, as the valve 44c is opened for a preset time period, the IPA(RT) is supplied onto the surface of the wafer W. The IPA(RT) supplied on the surface of the wafer W is diffused onto the entire surface of the wafer W by the centrifugal force which is generated when the wafer W is rotated (see FIG. 6A). Accordingly, the liquid on the surface of the wafer W is replaced by the IPA which has affinity to the water-repellent solution which will be discharged to the wafer W in the subsequent water-repellent processing. Further, since the IPA also has affinity to the DIW, replacing the DIW with the IPA is also easy.

Further, in the first replacement processing, to shorten the processing time, the replacement of the DIW with the IPA may be accelerated by supplying the HDIW to a rear surface of the wafer W. In this case, after supplying the HDIW to the rear surface of the wafer W for a predetermined time period, the supply of the HDIW to the rear surface of the wafer W may be stopped prior to stopping the supply of the IPA to the surface of the wafer W. By stopping the supply of the HDIW first, a temperature of the wafer W can be reduced. Therefore, it is possible to shorten the processing time while suppressing a reaction between the water-repellent solution and the IPA.

Here, in the first replacement processing, it may also be considered to supply the IPA heated to a high temperature. However, the IPA reacts with the water-repellent solution, and this reaction is accelerated as the temperature of the IPA gets higher. Thus, if the IPA of the high temperature is supplied to the wafer W in the first replacement processing, the reaction between the water-repellent solution and the IPA may take place before the water-repellent solution and the wafer W react with each other to form a water-repellent layer on the surface of the wafer W in the following water-repellent processing. In such a case, the water-repellent solution may not react with the surface of the wafer W, resulting in a failure of the water-repellent processing.

In view of this, in the present exemplary embodiment, the IPA having the first temperature, that is, the room temperature is used in the first replacement processing. Accordingly, the surface of the wafer W can be efficiently allowed to be water-repellent in the following water-repellent processing.

Further, although the first temperature is set to be the room temperature, the first temperature need not necessarily be the room temperature. From the viewpoint of not hindering the water-repellent processing on the surface of the wafer W, it is desirable that the first temperature is equal to or less than 35° C. As the temperature of the IPA becomes lower, it is difficult for the reaction between the IPA and the water-repellent solution to take place. If the temperature is equal to or less than at least 35° C., a pattern collapse can be appropriately suppressed. A heating unit configured to heat the IPA to a preset temperature equal to or less than 35° C. may be provided at the branch line 466 of the first IPA supply source 46c or the first branch line 468 of the IPA supply source 46f.

Further, the first temperature may be set to be equal to or less than the room temperature. In this case, a cooling unit configured to cool the IPA to a preset temperature equal to or less than the room temperature may be provided at the branch line 466 of the first IPA supply source 46c or the first branch line 468 of the IPA supply source 46f.

Subsequently, the water-repellent processing is performed in the processing unit 16 (process S105). In the water-repellent processing, a first water-repellent processing is performed first, and, then, a second water-repellent processing is performed.

In the first water-repellent processing, the nozzle 41d of the processing fluid supply unit 40 is placed above the central portion of the wafer W. Then, as the valve 44d is opened for a predetermined time period, the water-repellent solution having the room temperature is supplied onto the surface of the wafer W. The water-repellent solution of the room temperature supplied on the surface of the wafer W is diffused onto the entire surface of the wafer W by the centrifugal force which is generated by the rotation of the wafer W (see the upper drawing of FIG. 6B).

As stated above, in the first water-repellent processing, the water-repellent solution having the room temperature is supplied to the wafer W. Accordingly, as compared to a case of supplying the water-repellent solution of a high temperature, the reaction between the water-repellent solution and the IPA remaining on the surface of the wafer W can be suppressed. That is, the hindrance of the water-repellent processing on the surface of the wafer W can be suppressed.

In the first water-repellent processing, as the water-repellent solution is supplied onto the surface of the wafer W, a silyl group combines with an OH group on the surface of the wafer W, so that a water-repellent film is formed on the surface of the wafer W. For example, the first water-repellent processing is continued for an enough time period to remove the IPA remaining on the surface of the wafer W.

Here, in the first water-repellent processing, the water-repellent solution of the room temperature is supplied. However, the temperature of the water-repellent solution supplied in the first water-repellent processing is not particularly limited as long as it is equal to or less than 35° C., and may be heated to a temperature not excessing 35° C.

Subsequently, in the second water-repellent processing, while supplying the water-repellent solution of the room temperature onto the surface of the wafer W from the nozzle 41d after the first water-repellent processing, the HDIW is supplied to the rear surface of the wafer W by opening the valve 62 for a preset time period. The HDIW supplied to the rear surface of the wafer W is diffused onto the entire rear surface of the wafer W by the centrifugal force which is generated when the wafer W is rotated (see the lower drawing of FIG. 6B). Accordingly, the wafer W is heated to a second temperature, and the water-repellent solution on the wafer W is also heated to the second temperature by the heated wafer W. As the temperature of the water-repellent solution becomes higher, the reaction between the water-repellent solution and the wafer W is further accelerated. Therefore, since the reaction between the water-repellent solution and the wafer W is accelerated by heating the water-repellent solution, the wafer W can be allowed to be water-repellent in a shorter period of time. That is, the surface of the wafer W can be allowed to be water-repellent more efficiently.

Here, although the water-repellent solution is heated to the second temperature, that is, 70° C., the temperature of the water-repellent solution supplied in the second water-repellent processing is not particularly limited as long as the temperature of this water-repellent solution is higher than at least the temperature of the water-repellent solution supplied in the first water-repellent processing and lower than a boiling point (82.4° C.) of the IPA used in the second replacement processing. Within this range, the pattern collapse can be appropriately suppressed.

As stated above, in the water-repellent processing according to the present exemplary embodiment, the water-repellent solution equal to or less than 35° C. is supplied at least until the IPA remaining on the wafer W is removed, and, then, the water-repellent solution is heated to the temperature higher than 35° C. by heating the wafer W. Accordingly, the surface of the wafer W can be efficiently allowed to be water-repellent.

Thereafter, in the processing unit 16, the second replacement processing is performed (process S106). In the second replacement processing, the nozzle 41e of the processing fluid supply unit 40 is placed above the central portion of the wafer W. Then, as the valve 44e is opened for a preset time period, the IPA(HOT) is supplied onto the surface of the wafer W. The IPA(HOT) supplied on the surface of the wafer W is diffused onto the entire surface of the wafer W by the centrifugal force which is generated when the wafer W is rotated (see FIG. 6C). As a result, the water-repellent solution remaining on the surface of the wafer W is washed away by the IPA(HOT).

With an increase of the temperature of the IPA, the surface tension thereof is reduced. Thus, in the second replacement processing, by supplying the IPA heated to the second temperature lower than the boiling point of the IPA, the pattern collapse that might be caused by the surface tension of the IPA having entered gaps between patterns can be suppressed.

To obtain the effect of suppressing the pattern collapse, it is desirable that the second temperature is equal to or higher than at least 60° C. If the second temperature is equal to or higher than 60° C., it is possible to maintain the wafer W from a center to a periphery thereof at a high temperature. Further, since the temperature of the surface of the wafer W can be maintained higher than a dew-point temperature of the ambient air when the surface of the wafer W is exposed through a drying processing, the number of water marks caused by the condensation can be reduced.

Then, in the processing unit 16, the drying processing is performed (process S107). In the drying processing, by increasing the rotation speed of the wafer W for a preset time period, the IPA remaining on the wafer W is scattered away, so that the wafer W is dried.

Afterwards, in the processing unit 16, a carry-out processing is performed (process S108). In the carry-out processing, after stopping the rotation of the wafer W, the wafer W is carried out of the processing unit 16 by the substrate transfer device 17 (see FIG. 1). If this carry-out processing is completed, the series of substrate processings upon the single sheet of wafer W is ended.

As described above, the processing unit 16 according to the present exemplary embodiment is equipped with the substrate holding mechanism 30 (an example of a rotating unit) and the processing fluid supply unit 40 (an example of a processing liquid supply unit, a first organic solvent supply unit and a second organic solvent supply unit). The substrate holding mechanism 30 rotates the wafer W (an example of a substrate). The processing fluid supply unit 40 supplies the CDIW (an example of a processing liquid including water) to the wafer W. The processing fluid supply unit 40 supplies the IPA (an example of an organic solvent) of the room temperature (an example of a first temperature) to the wafer W after the supply of the CDIW. The processing fluid supply unit 40 supplies the water-repellent solution to the wafer W to allow the wafer W to be water-repellent. The processing fluid supply unit 40 supplies the IPA of 70° C. (an example of a second temperature) higher than the first temperature to the wafer W allowed to be water-repellent.

Therefore, in the processing unit 16 according to the present exemplary embodiment, it is possible to dry the wafer W while effectively suppressing the pattern collapse.

(Modification Example)

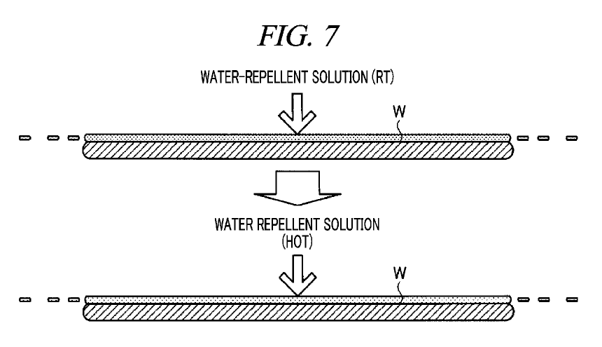

According to the above-described exemplary embodiment, in the water-repellent processing, after the water-repellent solution of the room temperature is supplied to the wafer W after being subjected to the first replacement processing, the water-repellent solution is supplied to the wafer W while the wafer W is heated. However, a sequence of the water-repellent processing is not limited to the above-stated example. In the following, a modification example of the water-repellent processing will be explained with reference to FIG. 7. FIG. 7 is an explanatory diagram for describing the water-repellent processing according to the modification example.

As depicted in FIG. 7, in the water-repellent processing according to the modification example, a first water-repellent processing and a second water-repellent processing are performed.

The first water-repellent processing according to the modification example is the same as the first water-repellent processing according to the above-described exemplary embodiment (see the upper drawing of FIG. 7) Thus, description of the first water-repellent processing will be omitted here.

In the second water-repellent processing according to the modification example, a water-repellent solution heated to the second temperature (water-repellent solution (HOT)) is supplied to the wafer W instead of a water-repellent solution of the room temperature (water-repellent solution (RT)) which is supplied in the first water-repellent processing. The water-repellent solution (HOT) supplied on the wafer W is diffused onto the entire surface of the wafer W by the centrifugal force which is generated when the wafer W is rotated (see the lower drawing of FIG. 7).

As discussed above, the water-repellent processing may include: the first water-repellent processing of supplying the water-repellent solution to the wafer W after being subjected to the first replacement processing; and the second water-repellent processing of supplying, to the wafer W after being subjected to the first water-repellent processing, the water-repellent solution of the temperature higher than the temperature of the water-repellent solution supplied in the first water-repellent processing.

In this case, a water-repellent solution (HOT) supply source configured to supply the water-repellent solution (HOT) is connected to the processing fluid supply unit 40 of the processing unit 16 in addition to the water-repellent solution supply source 46d. The water-repellent solution (HOT) may be discharged from the nozzle 41d configured to discharge the water-repellent solution (RT), or another nozzle for discharging the water-repellent solution (HOT) may be additionally provided at the processing fluid supply unit 40.

In the above-described exemplary embodiment, the IPA is used as the organic solvent supplied to the wafer W in the first replacement processing and the second replacement processing. However, the organic solvent supplied to the wafer W in the first replacement processing and the second replacement processing is not limited to the IPA as long as it has affinity to both the water and the water-repellent solution.

From the foregoing, it will be appreciated that the exemplary embodiment of the present disclosure has been described herein for purposes of illustration, and that various modifications may be made without departing from the scope and spirit of the present disclosure. Accordingly, the embodiment disclosed herein is not intended to be limiting. The scope of the inventive concept is defined by the following claims and their equivalents rather than by the detailed description of the exemplary embodiment. It shall be understood that all modifications and embodiments conceived from the meaning and scope of the claims and their equivalents are included in the scope of the inventive concept.

### EXPLANATION OF CODES

W: wafer

1: Substrate processing system

4: Control device

16: Processing unit

18: Control unit

30: Substrate holding mechanism

40: Processing fluid supply unit

46a: Chemical liquid supply source

46b: CDIW supply source

46c: First IPA supply source

46d: Water-repellent solution supply source

46e: Second IPA supply source

1. A substrate processing method, comprising:
a liquid processing process of supplying a processing liquid containing water to the substrate;
a first replacement process of replacing the processing liquid by supplying an organic solvent having a first temperature to the substrate after being subjected to the liquid processing process;
a water-repellent process of allowing the substrate to be water-repellent by supplying a water-repellent solution to the substrate after being subjected to the first replacement process;
a second replacement process of replacing the water-repellent solution by supplying the organic solvent having a second temperature higher than the first temperature to the substrate after being subjected to the water-repellent process; and
a drying process of removing the organic solvent from the substrate after being subjected to the second replacement process.

2. The substrate processing method of claim 1,
wherein the first temperature is a temperature at which a reaction between the substrate and the water-repellent solution is not hampered, as compared to the second temperature.

3. The substrate processing method of claim 2,
wherein the first temperature is equal to or less than 35° C., and
the second temperature is equal to or higher than 60° C.

4. The substrate processing method of claim 1,
wherein the water-repellent process comprises:
a first water-repellent process of supplying the water-repellent solution; and
a second water-repellent process of supplying, to the substrate after being subjected to the first water-repellent process, the water-repellent solution having a temperature higher than a temperature of the water-repellent solution supplied in the first water-repellent process.

5. The substrate processing method of claim 1,
wherein the water-repellent process comprises:
a first water-repellent process of supplying the water-repellent solution without heating the substrate; and
a second water-repellent process of supplying, to the substrate after being subjected to the first water-repellent process, the water-repellent solution while heating the substrate.

6. A substrate processing apparatus, comprising:
a rotating unit configured to rotate a substrate;
a processing liquid supply unit configured to supply a processing liquid containing water to the substrate;
a first organic solvent supply unit configured to supply an organic solvent having a first temperature to the substrate on which the processing liquid is supplied;
a water-repellent solution supply unit configured to supply a water-repellent solution to the substrate to allow the substrate to be water-repellent; and
a second organic solvent supply unit configured to supply the organic solvent having a second temperature higher than the first temperature to the substrate allowed to be water-repellent.

7. The substrate processing method of claim 2,
wherein the water-repellent process comprises:
a first water-repellent process of supplying the water-repellent solution; and
a second water-repellent process of supplying, to the substrate after being subjected to the first water-repellent process, the water-repellent solution having a temperature higher than a temperature of the water-repellent solution supplied in the first water-repellent process.

8. The substrate processing method of claim 3,
wherein the water-repellent process comprises:
a first water-repellent process of supplying the water-repellent solution; and
a second water-repellent process of supplying, to the substrate after being subjected to the first water-repellent process, the water-repellent solution having a temperature higher than a temperature of the water-repellent solution supplied in the first water-repellent process.

9. The substrate processing method of claim 2,
wherein the water-repellent process comprises:
a first water-repellent process of supplying the water-repellent solution without heating the substrate; and
a second water-repellent process of supplying, to the substrate after being subjected to the first water-repellent process, the water-repellent solution while heating the substrate.

10. The substrate processing method of claim 3,
wherein the water-repellent process comprises:
a first water-repellent process of supplying the water-repellent solution without heating the substrate; and
a second water-repellent process of supplying, to the substrate after being subjected to the first water-repellent process, the water-repellent solution while heating the substrate.
